(19) United States
(12) Patent Application Publication
(10) Pub. No.: US 2013/0308251 A1
(43) Pub. Date: Nov. 21, 2013

(54) COMPLEX TYPE SUPPORTING FRAME FOR ELECTRONIC DEVICES

(71) Applicants: Kuo-Tung TSENG, Taoyuan County (TW); Hoe-To Cho, Taoyuan County (TW)

(72) Inventors: Kuo-Tung TSENG, Taoyuan County (TW); Hoe-To Cho, Taoyuan County (TW)

(21) Appl. No.: 13/567,321

(22) Filed: Aug. 6, 2012

(30) Foreign Application Priority Data
May 15, 2012 (TW) 101209151

(51) Int. Cl. H05K 7/14

(52) U.S. Cl. 361/679.01

(57) ABSTRACT

A complex type supporting frame used to allow an electronic device to stand on or to be hung on a mounting surface. The complex type supporting frame includes a supporting part and a fixing part disposed surrounding the peripheral of the supporting part. The supporting part includes a device connection structure to support the electronic device. A positioning structure is disposed at the peripheral of the fixing part.

### CROSS-REFERENCE TO RELATED APPLICATION

This application claims the benefit of Taiwan Patent Application No. 101209151, filed on May 15, 2012, which is hereby incorporated by reference for all purposes as if fully set forth herein.

### BACKGROUND

1. Field of the Invention

The present invention relates to a supporting frame for electronic devices, and more particularly to a complex type supporting frame that may be used as a vertical stand or a supporting frame attached to vertical or horizontal plane for electronic devices.

2. Brief Description of the Related Art

Conventional electronic devices, such as computers, network appliances (for example, routers and hubs), display devices for computers or TVs (for example, liquid crystal, plasma, and LED), thin client computers, projection display equipments, and small barebones PCs, may be mounted to a fixing end such as an indoor wall or other equipments using a supporting frame. Alternatively, a vertical stand may be provided to allow the electronic device to stand vertically on a plane (for example, a table surface, a cabinet, or a bookshelf).

In practice, however, users tend to choose only one mounting device (a vertical stand or a supporting frame) to mount the electronic device based on their preferences, which means that one of the two will not be used at all. Yet, the manufacturers cannot anticipate all the users' preferences. Therefore, in order to enhance the convenience and applicability of the mounting process, the manufacturers sometimes provide both mounting devices (a vertical stand and a supporting frame) to go with one electronic device. This brings the needs of more packaging material and larger space, and increases the size of the product package. Further, the unused mounting device is easily forgotten and lost, making it difficult for the users to change their mounting method, thereby significantly lowering the convenience and applicability of the mounting process for the electronic devices.

### SUMMARY

In order to overcome the deficiencies of the prior art, the present invention provides a complex type supporting frame that may be used as a vertical stand or a supporting frame for electronic devices.

The complex type supporting frame of the present invention may be used to allow an electronic device to stand on or to be hung on a mounting surface. The complex type supporting frame includes a supporting part and a fixing part. The supporting part includes a device connection structure to support the electronic device. The fixing part is disposed surrounding the peripheral of the supporting part, and a positioning structure is disposed at the peripheral of the fixing part.

The complex type supporting frame of the present invention may be used as both a vertical stand that allowed the electronic device to stand and a supporting frame that is attached to vertical or horizontal plane, without having to concern about the users' individual preferences on mounting the electronic device. Therefore, the convenience and applicability of the mounting process may be enhanced. Further, since the complex type supporting frame of the present invention may be used as both a vertical stand and a supporting frame, one electronic device needs only one mounting device. This can reduce the requirement for packaging material, space the mounting device takes up, and the size of the product package. Or, in case of similar product package size, more assemblies may fit into the space, allowing the manufacturers to lower the cost and provide assemblies more efficiently. Moreover, since there's only one complex type supporting frame, and it may be used as a vertical stand and a supporting frame, no extra frame body will be forgotten, lost, or thrown away. This saves the additional cost for providing more than one mounting device, and also prevents the users to face a situation where they cannot change their electronic device mounting method. Further, the complex type supporting frame of the present invention combines the vertical stand and the supporting frame; therefore, it may save the amount of the material used to manufacture the product, and thereby saving the manufacturing cost. Further, the complex type supporting frame of the present invention may be used to support electronic devices, such as computers, network appliances (for example, routers and hubs), display devices for computers or TVs (for example, liquid crystal, plasma, and LED), thin client computers, projection display equipments, and small barebones PCs. That is, any electronic device having an attaching structure that matches the complex type supporting frame of the present invention is capable of being attached to the complex type supporting frame of the present invention. This allows the electronic device to stand vertically on a flat surface or to be hung on a vertical or horizontal surface (such as the wall, lateral side of another electronic device, or the bottom surface of a table), thus has better compatibility and applicability.

### BRIEF DESCRIPTION OF THE DRAWINGS

FIG. 1A illustrates a perspective view of a complex type supporting frame according to one embodiment of the present invention;

FIG. 1B illustrates a view showing a screw arrangement of a complex type supporting frame according to the embodiment of the present invention;

FIG. 1C illustrates a bottom view of a complex type supporting frame according to the embodiment of the present invention;

FIG. 2A illustrates a mounting view of a vertical stand of the complex type supporting frame according to one embodiment of the present invention;

FIG. 2B illustrates an exploded view of the vertical stand of the complex type supporting frame according to the embodiment of the present invention;

FIG. 3A illustrates a mounting view of a supporting seat of the complex type supporting frame according to one embodiment of the present invention;

FIG. 3B illustrates an exploded view of the supporting seat of the complex type supporting frame according to the embodiment of the present invention; and

FIG. 4 illustrates a mounting view of a display device mounted by the supporting seat of the complex type supporting frame according to one embodiment of the present invention.

### DETAILED DESCRIPTION OF THE EMBODIMENTS

Now, the preferred embodiment of the present invention will be described in detail with reference to the accompanying drawings.

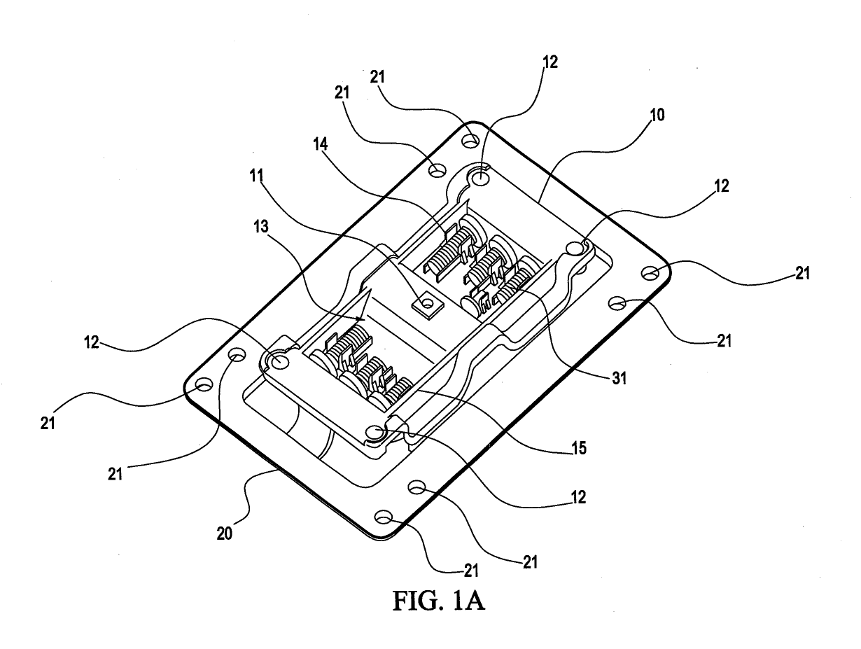

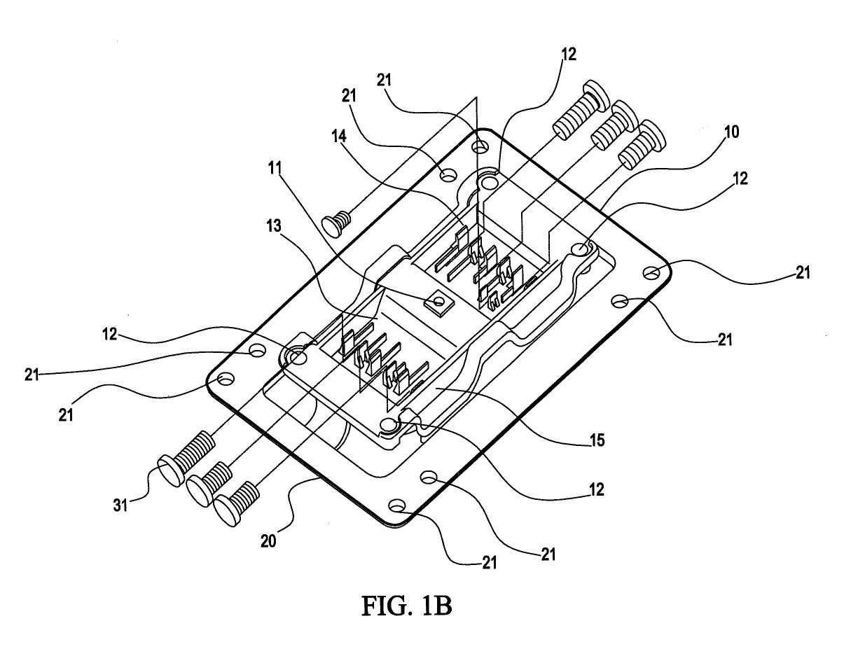

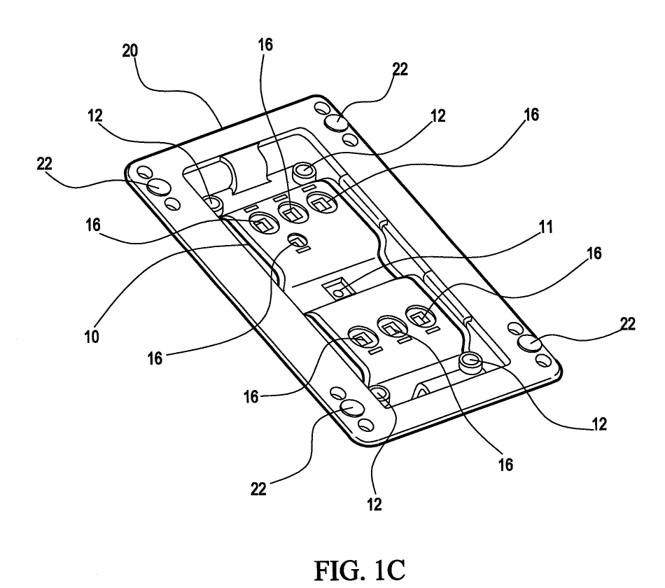

First, please refer to FIG. 1A to 1C, FIG. 1A illustrates a perspective view of a complex type supporting frame according to one embodiment of the present invention; FIG. 1B illustrates a view showing a screw arrangement of a complex type supporting frame according to the embodiment of the present invention; and FIG. 1C illustrates a bottom view of a complex type supporting frame according to the embodiment of the present invention.

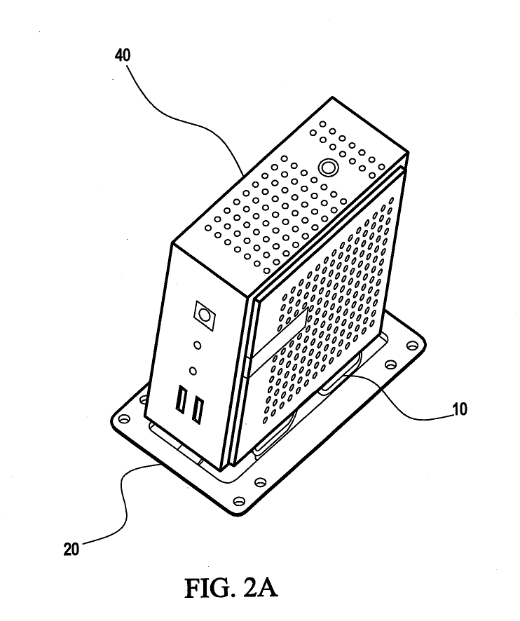

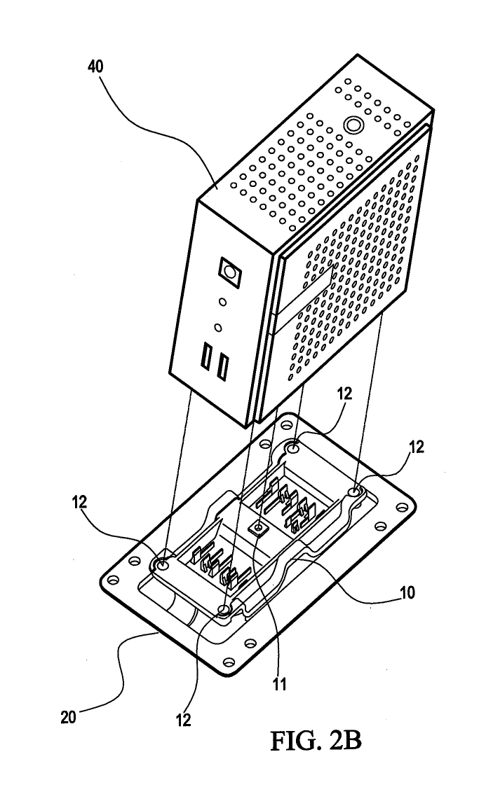

The complex type supporting frame includes a supporting part 10 and a fixing part 20. The supporting part 10 includes at least one device connection structure which is provided for connecting with an electronic device 40 (as shown in FIG. 2A). In the present embodiment, the device connection structure may be a locking member, a screw member, or a joint member. Further, one or more locking holes 11, 12 are provided in the supporting part 10. The locking holes 11, 12 may be formed in the figure center of the supporting part 10, the gravity center of the supporting part 10, any portion of the supporting part 10 that touches the electronic device 40, and/or a position around the peripheral of the supporting part 10. However, the device connection structure of the present invention is not limited to the locking member, the screw member, or the joint member; spring clamps, tension clips or any clipping structure that has similar configuration and shape may also be employed as the device connection structure, but is not limited thereto.

The supporting part 10 further includes a recess part 13. The recess part 13 is provided with a fixing clamp 14 at the inner side thereof to fix a screw member 31 such as screws or a locking member that may be used for screw or locking connection, or a joint member such as tenons.

However, the supporting part 10 may be an arc-shaped rectangular board or a wave-shaped rectangular board, but its shape is not limited thereto and may vary according to the need of the design. With different designs, the supporting part 10 may include one or a plurality of recess parts 13, and each recess part 13 may be disposed of one or a plurality of fixing clamp 14. Moreover, both sides of the supporting part 10 may include a plurality of stop plates 15 to enhance the strength of the shape of the supporting part 10, and prevent the user's fingers from directly contacting the screw member 31, the locking member or the joint member, thus to prevent their fingers from being cut by the screw member 31, the locking member or the joint member. Further, the opening direction of the recess part 13 is not limited herein.

Further, in the supporting part 10, a through hole 16 is formed in a position adjacent to the fixing clamp 14. When the screw member 31, the locking member or the joint member is fixed at the fixing clamp 14, the user may use a tool with a fine and long cylinder shape or a needle shape to go through the through hole 16 and pressingly touch the screw member 31, the locking member or the joint member, thereby detaching the screw member 31, the locking member or the joint member from the fixing clamp 14.

The fixing part 20 is disposed surrounding the peripheral of the supporting part 10, and is slightly stepped from the supporting part 10. The fixing part 20 includes more than one positioning structures disposed at the peripheral thereof. In the present embodiment, the positioning structure includes two kinds of members: washer 22 and locking hole 21.

The washer 22 is disposed surrounding a surface of the fixing part 20. The surface contacts a mounting surface. The mounting surface refers to a plane (horizontal flat surface such as a table surface, a cabinet, a bookshelf, or the floor) on which the electronic device 40 is disposed, or a place where the electronic device 40 is fixed to (such as a wall, lateral side surface of another electronic device, or the bottom surface of a table). The washer 22 may be or may not be disposed; the present invention is not limited thereto, and may vary according to the need of the product design.

The aforesaid locking hole 21 is disposed surrounding the peripheral of the fixing part 20 at a position determined according to the need of the product design or standard specification requirements of other relating device, for instance, the VESA mounting interface standard for displays. The VESA mounting interface standard refers to: a hole pattern on the back of a general display backboard 50 is 3″×3″ or 4″×4″ (75 mm×75 mm or 100 mm×100 mm), and the diameter of the screw member 31 is 4 mm.

Further, please refer to FIG. 2A and FIG. 2B, FIG. 2A illustrates a mounting view of a vertical stand of the complex type supporting frame according to one embodiment of the present invention; and FIG. 2B illustrates an exploded view of the vertical stand of the complex type supporting frame according to the embodiment of the present invention.

In the present embodiment, the supporting part 10 may be locked or screw-connected to a lateral side of the electronic device 40 by using the locking hole 11 provided at the figure center of the supporting part 10 and/or the locking hole 12 disposed at the peripheral of the supporting part 10, with the screw 31 or the locking member. The complex type supporting frame then become a vertical stand for the electronic device 40, allowing the electronic device 40 to vertically stand on horizontal flat surfaces such as a table surface, a cabinet, a bookshelf, or the floor.

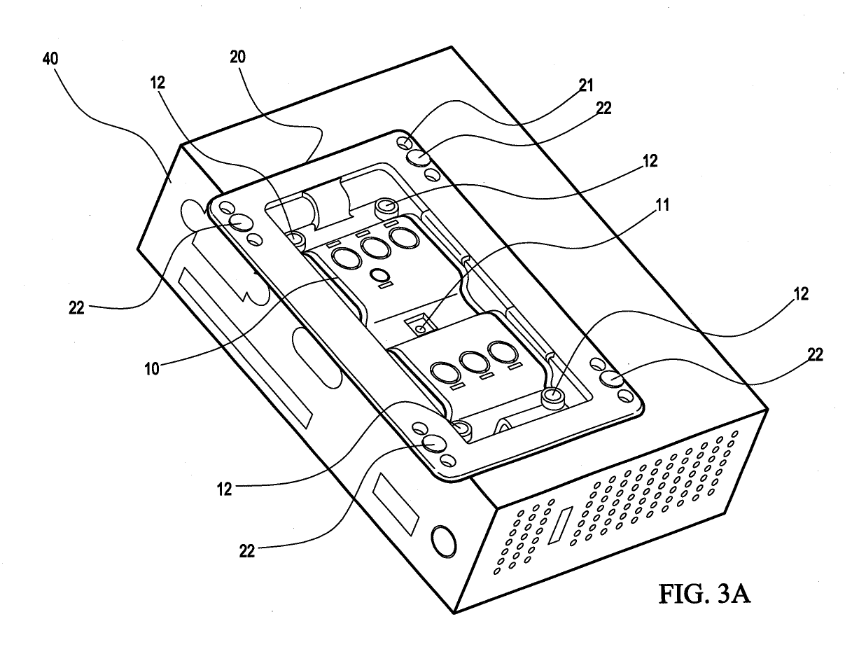

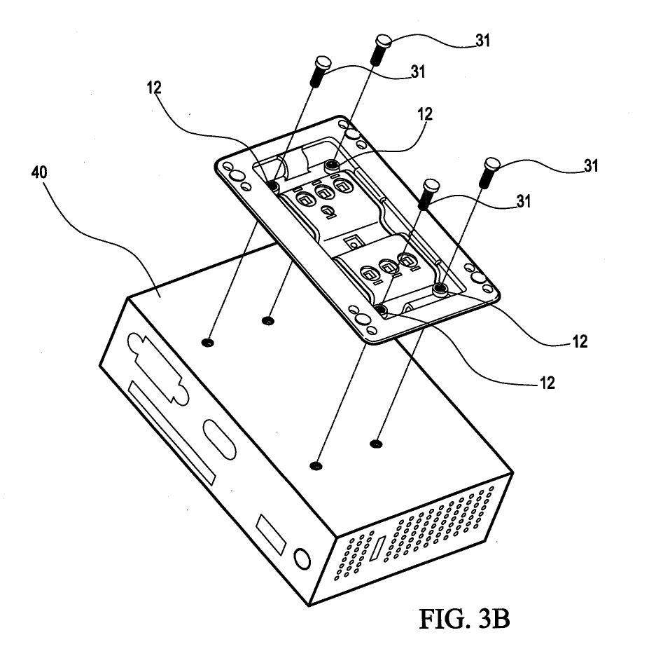

Further, please refer to FIG. 3A and FIG. 3B, FIG. 3A illustrates a mounting view of a supporting seat of the complex type supporting frame according to one embodiment of the present invention; and FIG. 3B illustrates an exploded view of the supporting seat of the complex type supporting frame according to the embodiment of the present invention.

In the present embodiment, the supporting part 10 may be locked or screw-connected to a lateral side surface of the electronic device 40 by using the locking hole 11 provided at the figure center of the supporting part 10 and/or the locking hole 12 disposed at the peripheral of the supporting part 10, with the screw member 31, the locking member or the joint member. The complex type supporting frame then become a supporting frame for hanging the electronic device 40 on a vertical or horizontal flat surface, such as a wall, lateral side surface of another electronic device or bottom surface of a table, allowing the electronic device 40 to be hung on an indoor wall or other electronic devices.

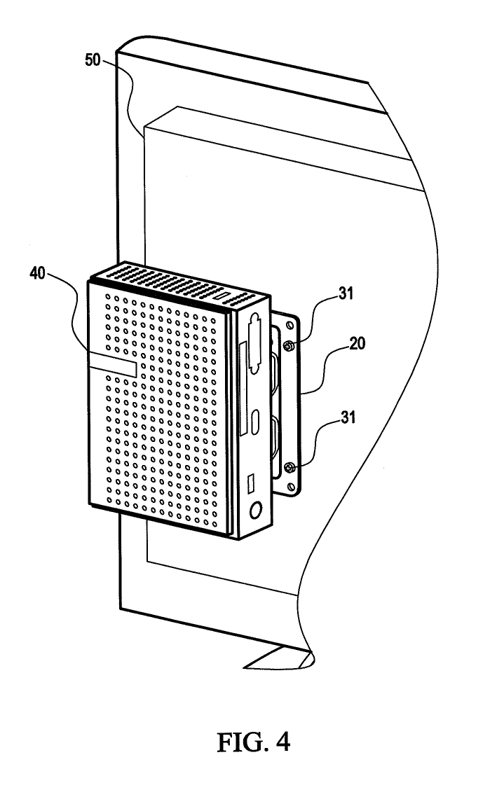

Further, please refer to: FIG. 4, it illustrates a mounting view of a display device mounted by the supporting seat of the complex type supporting frame according to one embodiment of the present invention. In the present embodiment, the fixing part 20 is closely attached to the backboard of the display device, and part or all of the locking holes 21 disposed at the peripheral of the fixing part 20 align with screw holes on the display backboard 50 that match the VESA mounting interface standard. The fixing part 20 is fixed to the display backboard 50 by locking or screw-connecting through some or all of the locking holes 21 or by jointing to the display backboard 50. By using the complex type supporting frame, the electronic device 40 can be fixed to the display backboard.

The previous description of the preferred embodiment is provided to further describe the present invention, not intended to limit the present invention. Any modification apparent to those skilled in the art according to the disclosure within the scope will be construed as being included in the present invention.

What is claimed is:

1. A complex type supporting frame applied to allow an electronic device to stand on or to be hung at a mounting surface, comprising:
a supporting part supporting the electronic device, wherein the supporting part includes a device connection structure; and
a fixing part, disposed surrounding peripheral of the supporting part, and at least one positioning structure is disposed at peripheral of the fixing part.

2. The complex type supporting frame of claim 1, wherein the device connection structure comprises at least one locking hole, and the supporting part is attached to the electronic device by locking or screw-connecting through the locking hole, or by jointing to the electronic.

3. The complex type supporting frame of claim 2, wherein the supporting part is disposed with the locking hole.

4. The complex type supporting frame of claim 2, wherein the device connection structure is disposed with the locking hole.

5. The complex type supporting frame of claim 1, wherein the positioning structures include a plurality of locking holes, and the locking holes are disposed at the peripheral of the fixing part, and the fixing part is fixed to the mounting surface by locking or screw-connecting through some or all of the locking holes, or by jointing.

6. The complex type supporting frame of claim 1, wherein the supporting part comprises a recess part.

7. The complex type supporting frame of claim 6, wherein the recess part is disposed of at least one of a locking member, a screw member, or a joint member.

8. The complex type supporting frame of claim 6, wherein a fixing clamp is disposed at inner side of the recess part.

9. The complex type supporting frame of claim 8, wherein the fixing clamp is used for clamping and supporting at least one of the locking member, the screw member, or the joint member.

10. The complex type supporting frame of claim 6, wherein a through hole is formed in a position of the supporting part adjacent to the fixing clamp.

11. The complex type supporting frame of claim 1, wherein a plurality of stop plates is disposed at both sides of the supporting part.
